(19) United States
(12) Patent Application Publication
(10) Pub. No.: US 2024/0290913 A1
(43) Pub. Date: Aug. 29, 2024

(54) ELECTRONIC DEVICE

(71) Applicant: InnoLux Corporation, Miao-Li County (TW)

(72) Inventors: Jia-Yuan CHEN, Miao-Li County (TW); Tsung-Han TSAI, Miao-Li County (TW); Kuan-Feng LEE, Miao-Li County (TW)

(73) Assignee: InnoLux Corporation, Miao-Li County (TW)

(21) Appl. No.: 18/415,679

(22) Filed: Jan. 18, 2024

Related U.S. Application Data
(60) Provisional application No. 63/447,900, filed on Feb. 24, 2023.

(30) Foreign Application Priority Data
Nov. 14, 2023 (CN) 202311508875.8

(51) Int. Cl. H01L 33/38; H01L 23/00; H01L 25/07; H01L 25/075; H01L 25/16; H01L 29/417; H01L 29/423

(52) U.S. Cl. CPC H01L 33/382; H01L 24/24; H01L 25/0753; H01L 25/167; H01L 29/41758; H01L 29/4238; H01L 25/072; H01L 2224/24146; H01L 2224/24147; H01L 2224/24226; H01L 2224/24227

(57) ABSTRACT

An electronic device is provided by the present disclosure. The electronic device includes a substrate and at least one electronic unit. The substrate has at least one recess, and the at least one electronic unit is disposed in the at least one recess. The at least one electronic unit has N1 signal connecting points, wherein N1 is greater than or equal to 1. In a top view direction of the electronic device, the at least one recess has a maximum size D1, the at least one electronic unit has a maximum size C1, and the maximum size D1 and the maximum size C1 satisfies: 0<D1−C1<C1/N1.

### CROSS REFERENCE TO RELATED APPLICATION

This application claims the benefit of U.S. Provisional Application No. 63/447,900, filed on Feb. 24, 2023. The content of the application is incorporated herein by reference.

### BACKGROUND OF THE DISCLOSURE

### 1. Field of the Disclosure

The present disclosure relates to an electronic device, and more particularly to an electronic device formed through fluid transfer process.

### 2. Description of the Prior Art

The electronic units can be transferred to the target substrate through mass transfer technology, such as fluid transfer technology, thereby achieving mass production. However, when the electronic units are transferred through fluid transfer process, the electronic units may not be disposed in order. Therefore, the difficulty of the subsequent forming process of wires may increase, or abnormal condition of electrical connection of the electronic units may occur to affect the yield of the electronic device. Therefore, to improve the process of the fluid transfer process or improve the yield of the electronic device formed through fluid transfer process is still an important issue in the present field.

### SUMMARY OF THE DISCLOSURE

The present disclosure aims at providing an electronic device.

In some embodiments, the present disclosure provides an electronic device including a substrate and at least one electronic unit. The substrate has at least one recess, and the electronic unit is disposed in the recess. The electronic unit has N1 signal connecting points, wherein N1 is greater than or equal to 1. In a top view direction of the electronic device, the recess has a maximum size D1, the electronic unit has a maximum size C1, and the maximum size D1 and the maximum size C1 satisfies:

0<D1−C1<C1/N1.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to a first embodiment of the present disclosure.

FIG. 2 schematically illustrates top views of the electronic unit and the recess according to an embodiment of the present disclosure.

FIG. 3A schematically illustrates top views of the electronic unit and the recess according to the first embodiment of the present disclosure.

FIG. 3B schematically illustrates top views of the electronic unit and the recess according to a variant embodiment of the first embodiment of the present disclosure.

FIG. 4 schematically illustrates top views of the electronic unit and the recess according to another variant embodiment of the first embodiment of the present disclosure.

FIG. 5 schematically illustrates a cross-sectional view of an electronic unit according to a second embodiment of the present disclosure.

FIG. 6 schematically illustrates a top view of the electronic unit according to the second embodiment of the present disclosure.

FIG. 7 schematically illustrates a top view of an electronic unit according to a variant embodiment of the second embodiment of the present disclosure.

FIG. 8 schematically illustrates a cross-sectional view of an electronic unit according to a third embodiment of the present disclosure.

FIG. 9 schematically illustrates a cross-sectional view of an electronic unit according to a fourth embodiment of the present disclosure.

FIG. 10 schematically illustrates a cross-sectional view of an electronic unit according to a fifth embodiment of the present disclosure.

FIG. 11 schematically illustrates a cross-sectional view of an electronic unit according to a sixth embodiment of the present disclosure.

FIG. 12 schematically illustrates top views of the electronic unit and the recess according to a seventh embodiment of the present disclosure.

FIG. 13 schematically illustrates top views of the electronic unit and the recess according to a variant embodiment of the seventh embodiment of the present disclosure.

FIG. 14 schematically illustrates a top view of an electronic unit according to an eighth embodiment of the present disclosure.

FIG. 15 schematically illustrates a cross-sectional view of the electronic unit according to the eighth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within +20%, +10%, +5%, +3%, +2%, +1%, or +0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device or other suitable electronic devices, but not limited thereto. The electronic device of the present disclosure may include any suitable device applied to the above-mentioned devices. The electronic device may be a foldable electronic device, a flexible electronic device or a stretchable electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device or a non-liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements or active elements, such as capacitor, resistor, inductor, diode, transistor, sensors, integrated circuits, memories, and the like. The electronic units may include the integrated electronic units formed by encapsulating the above-mentioned electronic units, such as the chip formed by encapsulating the integrated circuit and the memory. The diode may include a light emitting diode or a photo diode. The light emitting diode may for example include an organic light emitting diode (OLED) or an inorganic light emitting diode. The inorganic light emitting diode may for example include a mini light emitting diode (mini LED), a micro light emitting diode (micro LED) or a quantum dot light emitting diode (QLED), but not limited thereto. It should be noted that the electronic device of the present disclosure may be combinations of the above-mentioned devices, but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices.

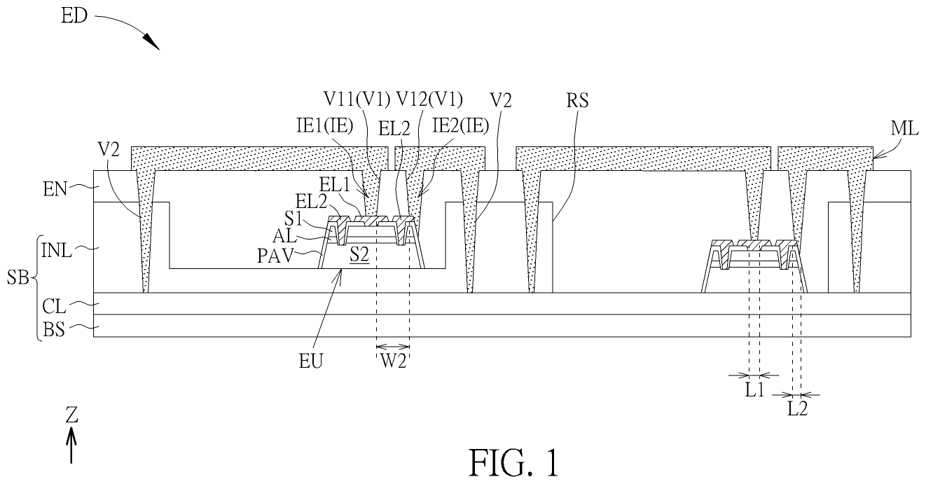

Referring to FIG. 1, FIG. 1 schematically illustrates a cross-sectional view of an electronic device according to a first embodiment of the present disclosure. According to the present embodiment, as shown in FIG. 1, the electronic device ED includes a substrate SB and at least one electronic unit EU, wherein the substrate SB includes at least one recess RS, and the electronic units EU is disposed in the recess RS. Specifically, the substrate SB may include a base BS, a circuit layer CL disposed on the base BS and an insulating layer INL disposed on the circuit layer CL, wherein the recess RS may be disposed in the insulating layer INL. According to the present disclosure, the electronic units EU of the electronic device ED may be transferred from other substrate to the substrate SB through fluid transfer process and be disposed in the recess RS of the substrate SB, thereby forming the electronic device ED. In detail, the liquid (not shown) including the electronic units EU may be dropped on the substrate SB, or the substrate SB may be put in a liquid sink having the electronic units EU, and the electronic units EU may be dropped into the recesses RS, such that the electronic units EU are disposed in the recesses RS. In the present embodiment, the substrate SB includes a plurality of recesses RS, and one of the electronic units EU is disposed corresponding to one of the recesses RS after the fluid transfer process, that is, one of the electronic units EU is disposed in one of the recesses RS, but not limited thereto. The features of the layers and the elements of the electronic device ED will be detailed in the following.

The base BS may be used to support the elements and/or the layers disposed thereon. The base BS may include rigid materials or flexible materials. The rigid materials for example include glass, quartz, sapphire, ceramic, other suitable materials or combinations of the above-mentioned materials, and the flexible materials for example include polyimide (PI), polycarbonate (PC), polyethylene terephthalate (PET), other suitable materials or combinations of the above-mentioned materials, but not limited thereto. It should be noted that although the base BS shown in FIG. 1 includes a single-layer structure, the present disclosure is not limited thereto. In some embodiments, the base BS may include a multi-layer structure formed of the above-mentioned materials.

The circuit layer CL may be disposed on the base BS. The circuit layer CL may include various kinds of wires, circuits, electronic units (such as active elements and/or passive elements) that can be applied to the electronic device ED, but not limited thereto. For example, although it is not shown in FIG. 1, the circuit layer CL may include driving units, wherein the driving units may be electrically connected to any suitable electronic unit in the electronic device ED, such as the electronic units EU. Therefore, the switching or operation of the electronic units EU may be controlled by the driving units in the circuit layer CL. The circuit layer CL may further include other suitable elements, which is not limited to the contents above. In the present embodiment, the circuit layer CL may include a structure formed by stacking a plurality of insulating layers and a plurality of conductive layers, but not limited thereto.

The insulating layer INL may be disposed on the circuit layer CL. In the present embodiment, the recess RS may be formed by removing a portion of the insulating layer INL. Specifically, a portion of the insulating layer INL may be removed according to the predetermined disposition position of the electronic units EU of the electronic device ED to form the at least one recess RS, such that the electronic units EU may be dropped in the recesses RS in the subsequent fluid transfer process, thereby making the electronic units EU disposed in the predetermined disposition position. In some embodiments, as shown in the left part of FIG. 1, the recess RS may not penetrate through the insulating layer INL, that is, the recess RS may not expose the circuit layer CL, but not limited thereto. Therefore, the possibility that the circuit layer CL is damaged during the transferring process of the electronic units EU may be reduced. In some embodiments, as shown in the right part of FIG. 1, the recess RS may penetrate through the insulating layer INL. The insulating layer INL may include any suitable insulating material, such as inorganic insulating materials or organic insulating materials. It should be noted that although the insulating layer INL shown in FIG. 1 includes a single-layer structure, the present disclosure is not limited thereto. In some embodiments, the insulating layer INL may include a multi-layer structure formed by stacking a plurality of insulating layers, and the recess RS may be formed by removing portions of the insulating layers.

In another embodiment, although it is not shown in FIG. 1, the insulating layer INL may directly be disposed on the base BS, and the electronic units EU may be disposed in the recesses RS at a certain distance, wherein the electronic units EU will be picked up from the recesses RS in the subsequent process and be electrically connected to another circuit substrate through bonding.

The electronic unit EU may include any suitable semiconductor unit based on the type of the electronic device ED. For example, in the present embodiment, the electronic device ED may include a display device, and the electronic unit EU may include any suitable light emitting unit, such as light emitting diode, but not limited thereto. FIG. 1 shows the condition that the electronic unit EU includes the inorganic light emitting diode. In such condition, the electronic unit EU may include a first semiconductor layer S1, a second semiconductor layer S2 and an active layer AL disposed between the first semiconductor layer S1 and the second semiconductor layer S2. One of the first semiconductor layer S1 and the second semiconductor layer S2 may be a P-type semiconductor layer, and another one of the first semiconductor layer S1 and the second semiconductor layer S2 may be a N-type semiconductor layer. The active layer AL for example includes a multiple quantum well (MQW) structure, but not limited thereto. In addition, the electronic unit EU may further include a first electrode EL1 electrically connected to the first semiconductor layer S1 and a second electrode EL2 electrically connected to the second semiconductor layer S2. One of the first electrode EL1 and the second electrode EL2 may be a P electrode, and another one of the first electrode EL1 and the second electrode EL2 may be a N electrode. The detailed structure of the electronic unit EU will be detailed in the following. It should be noted that the structure of the electronic unit EU shown in FIG. 1 is exemplary, and the present disclosure is not limited thereto. In some embodiments, the electronic unit EU may include other suitable light emitting unit. In some embodiments, the electronic device ED may include a sensing device, and the electronic unit EU may include any suitable sensing element. In some embodiments, the electronic device ED may include an antenna device (such as a liquid crystal antenna), and the electronic unit EU may include any suitable semiconductor element capable of receiving/transmitting micro wave signals. The contents of the present disclosure will be detailed by taking the inorganic light emitting diode as an example of the electronic unit EU, but the present disclosure is not limited thereto.

According to the present embodiment, as shown in FIG. 1, the electronic device ED further includes an encapsulation layer EN and a conductive layer ML, but not limited thereto. The encapsulation layer EN may be disposed on the insulating layer INL and cover the electronic units EU, thereby encapsulating the electronic units EU. Specifically, the encapsulation layer EN may be filled into the recesses RS of the insulating layer INL. In addition, the encapsulation layer EN may provide a flat surface to facilitate the disposition of other elements or layers (such as the conductive layer ML) thereon. The encapsulation layer EN may include any suitable encapsulating material. The encapsulation layer EN may provide protection to the electronic units EU. The encapsulation layer EN may include a single-layer structure or a multi-layer structure.

According to the present embodiment, the conductive layer ML may be disposed on the encapsulation layer EN for electrically connecting the electronic units EU to the circuit layer CL. For example, the conductive layer ML may electrically connect the electronic units EU to the driving units in the circuit layer CL, but not limited thereto. Specifically, the electronic device ED may include at least one via V1, the via V1 may be formed by removing a portion of the encapsulation layer EN, and the conductive layer ML may be filled into the via V1 and contact the bonding element of the electronic unit EU, thereby being electrically connected to the electronic unit EU. The bonding element of the electronic unit EU described here may include the electrodes of the electronic unit EU, such as the first electrode EL1 and the second electrode EL2 mentioned above, but not limited thereto. The vias V1 may be disposed corresponding to the first electrode EL1 and the second electrode EL2. Specifically, in a top view direction of the electronic device ED (that is, parallel to the direction Z, which will not be redundantly described in the following), the vias V1 may include a first via V11 and a second via V12, the first via V11 may at least partially overlap the first electrode EL1 of the electronic unit EU, and the second via V12 may at least partially overlap the second electrode EL2 of the electronic unit EU, such that the conductive layer ML may be electrically connected to the first electrode EL1 and the second electrode EL2. In detail, in normal condition, the first via V11 and the second via V12 may respectively penetrate the encapsulation layer EN and expose the first electrode EL1 and the second electrode EL2 of the electronic unit EU, and different portions of the conductive layer ML may respectively be filled into the two vias and contact the first electrode EL1 and the second electrode EL2. In the present embodiment, the portion of the conductive layer ML filled into the via V1 may be called the interconnection element IE, that is, the first electrode EL1 and the second electrode EL2 of the electronic unit EU may respectively be electrically connected to the interconnection element IE1 disposed in the first via V11 and the interconnection element IE2 disposed in the second via V12. In addition, the electronic device ED further includes at least one via V2, wherein the via V2 may be formed by removing a portion of the encapsulation layer EN and a portion of the insulating layer INL, and the via V2 may expose a portion of the circuit layer CL or expose the electronic element in the circuit layer CL. For example, the via V2 may expose the driving unit or other electronic elements which are electrically connected to the driving unit in the circuit layer CL. The conductive layer ML may be filled into the via V2 and contact the electronic element in the circuit layer CL, thereby being electrically connected to the electronic element in the circuit layer CL. Therefore, the electronic unit EU may be electrically connected to the circuit layer CL (or the electronic element in the circuit layer CL) through the conductive layer ML. For example, as shown in FIG. 1, the first electrode EL1 of the electronic unit EU may be electrically connected to a portion of the conductive layer ML through the first via V11 (or the interconnection element IE1), and the portion of the conductive layer ML may be electrically connected to an electronic element in the circuit layer CL through a via V2; the second electrode EL2 of the electronic unit EU may be electrically connected to another portion of the conductive layer ML through the second via V12 (or the interconnection element IE2), and the another portion of the conductive layer ML may be electrically connected to another electronic element in the circuit layer CL through another via V2. The conductive layer ML may include any suitable conductive material. It should be noted that although the conductive layer ML shown in FIG. 1 includes a single-layer structure, the present disclosure is not limited thereto. In some embodiments, the conductive layer ML may include a conductive structure formed by stacking insulating layer (s) and conductive layer (s), and the electronic unit EU may be electrically connected to the circuit layer CL through the conductive layer (s) in the conductive structure.

It should be noted that the electronic device ED may further include other elements or layers and is not limited to the structure mentioned above. For example, in some embodiments, the electronic device ED may further include the layer (s) or element (s) disposed on the conductive layer ML, such as a cover layer, to provide protection of the conductive layer ML.

According to the present disclosure, a bonding element for transmitting electrical signals in the electronic unit EU of the electronic device ED may be regarded as a signal connecting point of the electronic unit EU. In other words, the electronic unit EU may transmit electrical signals to the interconnection element IE or receive electrical signals from the interconnection element IE through the signal connecting point. The electronic unit EU may have at least one signal connecting point, wherein the number of the signal connecting point may be determined according to the number of the bonding element of the electronic unit EU. Specifically, the number of the signal connecting point of the electronic unit EU may be the same as the number of the bonding element of the electronic unit EU. For example, in the present embodiment, the electronic unit EU may include the inorganic light emitting diode and thereby including a P electrode and a N electrode (that is, the first electrode EL1 and the second electrode EL2) for transmitting electrical signals, wherein an electrode of the electronic unit EU may be regarded as a signal connecting point. In other words, the electronic unit EU of the present embodiment may be regarded as having two signal connecting points. It should be noted that depending on the type of the electronic unit EU, the electronic unit EU may include the bonding element of different numbers, and therefore, the electronic unit EU may have the signal connecting points of different numbers. The definition of the signal connecting point in the following may refer to the contents mentioned above, and will not be redundantly described.

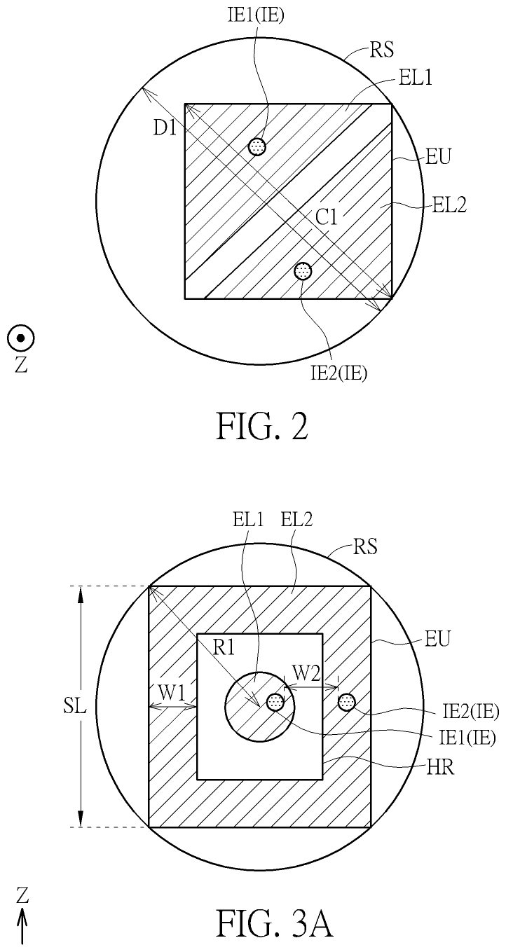

Referring to FIG. 2, FIG. 2 schematically illustrates top views of the electronic unit and the recess according to an embodiment of the present disclosure. In order to simplify the figure, FIG. 2 just shows the top views of a recess RS and an electronic unit EU disposed in the recess RS. According to the present embodiment, in the top view direction of the electronic device ED, the recess RS has a maximum size D1, and the electronic unit EU has a maximum size C1. The maximum size D1 of the recess RS may be defined as the maximum distance in the shape of the projection (hereinafter referred to as the projected shape) of the recess RS on a plane perpendicular to the top view direction of the electronic device ED. In some embodiments, when the projected shape of the recess RS is a circle (as shown in FIG. 2), the maximum size D1 of the recess RS may be defined as the diameter of the circle. In some embodiments, when the projected shape of the recess RS is an oval, the maximum size D1 of the recess RS may be defined as the length of the major axis of the oval. In some embodiments, when the projected shape of the recess RS is a rectangle, the maximum size D1 of the recess RS may be defined as the length of the diagonal of the rectangle. In some embodiments, when the projected shape of the recess RS is a polygon, the maximum size D1 of the recess RS may be defined as the length of the longest diagonal of the polygon. The definition of the maximum size C1 of the electronic unit EU may refer to the definition of the maximum size D1 of the recess RS mentioned above, and will not be redundantly described. In addition, the electronic unit EU of the present embodiment may have N1 signal connecting point, wherein N1 is greater than or equal to 1. For example, since the electronic unit EU of the present embodiment includes the first electrode EL1 and the second electrode EL2, N1 may be 2, but not limited thereto. According to the present disclosure, the maximum size D1 of the recess RS, the maximum size C1 of the electronic unit EU and the number N1 of the signal connecting point of the electronic unit EU may satisfy the following equation (1):

$$0 < D 1 - C 1 < C 1 / N 1 \qquad ( 1 )$$

For example, in the present embodiment, since N1 is 2, it can be known from the equation (1) that D1−C1<C1/2, but not limited thereto. In some embodiments, the electronic unit EU may include three bonding elements, that is, the electronic unit EU may include three signal connecting points. In such condition, it can be known from the equation (1) that D1−C1<C1/3.

According to the present disclosure, by making the maximum size D1 of the recess RS and the maximum size C1 of the electronic unit EU satisfy the equation (1) above, the bonding between the electronic unit EU and the conductive layer ML may be improved under the condition that the manufacturing process of the conductive layer ML is simplified. Specifically, by making D1−C1 (that is, the difference between the maximum size D1 and the maximum size C1) lower than C1/N1, the condition that the conductive layer ML fails to be bonded to the electronic unit EU under a fixed configuration of the conductive layer ML may be reduced. “The conductive layer ML has a fixed configuration” described herein may include the embodiments that the interconnection elements IE (or the vias V1), in the conductive layer ML, which are electrically connected to different electronic units EU are substantially corresponding to the same relative position in different recesses RS, but not limited thereto. In other words, the predetermined disposition positions of the interconnection elements IE (or the vias V1) in each of the recesses RS may substantially be the same. For example, as shown in FIG. 2, the conductive layer ML may include two interconnection elements IE (that is, the interconnection element IE1 and the interconnection element IE2) corresponding to a recess RS, the two interconnection elements IE are predetermined to respectively be electrically connected to the first electrode EL1 and the second electrode EL2 of the electronic unit EU, and in the present embodiment, the relative positions of the two interconnection elements IE in the recess RS may substantially be the same as the relative positions of other interconnection elements IE in other recesses RS. The predetermined disposition position of the interconnection element IE may be determined according to the disposition position of the electrode of the electronic unit EU. It should be noted that the conductive layer ML is not shown in FIG. 2, and the interconnection element IE labeled in FIG. 2 may be the projection of the bottom of the interconnection element IE on the plane perpendicular to the direction Z, that is, the projection of the bottom of the via V1 on the plane perpendicular to the direction Z. Specifically, as shown in FIG. 2, by making D1−C1 lower than C1/2, even if the electronic unit EU is disposed too biased toward (or too close to) a side of the recess RS, or the electronic device EU is too offset from the center of the recess RS, the possibility that the disposition positions of the interconnection elements IE of the conductive layer ML (or the disposition positions of the vias V1) overlap the first electrode EL1 and the second electrode EL2 of the electronic unit EU may increase under the condition that the configuration of the conductive layer ML is fixed. Therefore, abnormal electrical connection caused by the interconnection element IE not contacting the first electrode EL1 and/or the second electrode EL2 may be reduced, thereby improving the yield of the electronic device ED. In a comparative example, if D1−C1 is greater than C1/2, the difference between the maximum size D1 of the recess RS and the maximum size C1 of the electronic unit EU may be excessively great. In such condition, when the electronic unit EU is too offset from the center of the recess RS, the first electrode EL1 and/or the second electrode EL2 of the electronic unit EU may not overlap the interconnection elements IE with the fixed disposition position, such that the first electrode EL1 and/or the second electrode EL2 may not be electrically connected to the conductive layer ML, or additional change of the disposition position of the interconnection elements IE may be required, thereby increasing the difficulty of the manufacturing process of the conductive layer ML. In addition, when D1−C1 is lower than 0, the maximum size D1 of the recess RS is lower than the maximum size C1 of the electronic unit EU. In such condition, the electronic unit EU may not be disposed in the recess RS, thereby reducing the yield of the electronic device ED.

It should be noted that the patterns of the first electrode EL1 and the second electrode EL2 shown in FIG. 2 are exemplary, and the present disclosure is not limited thereto. In addition, although it is not shown in FIG. 2, the design of the sizes of other recesses RS and other electronic units EU in the electronic device ED may refer to the contents mentioned above. Moreover, the size of the recess RS and the size of the electronic unit EU in each of the embodiments may both satisfy the equation (1), such that the electrical connection of the electronic unit EU may be improved. The above-mentioned feature will not be redundantly described in the following.

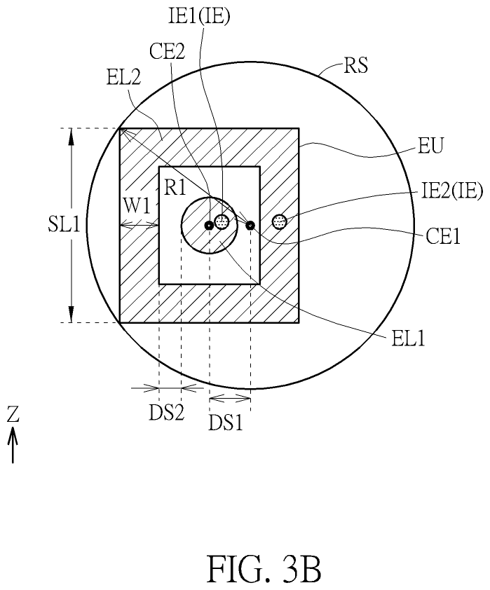

Referring to FIG. 3A, FIG. 3A schematically illustrates top views of the electronic unit and the recess according to the first embodiment of the present disclosure. According to the present embodiment, in the top view direction of the electronic device ED, the electrodes of the electronic unit EU (for example, the first electrode EL1 and the second electrode EL2) may be designed to be symmetrical. Specifically, as shown in FIG. 3A, in the top view direction of the electronic device ED, one of the electrodes of the electronic unit EU (for example, the first electrode EL1, but not limited thereto) may have any suitable solid pattern and substantially be disposed at the center of the electronic unit EU, and another one of the electrodes of the electronic unit EU (for example, the second electrode EL2, but not limited thereto) may be ring-shaped or have any suitable symmetrical shape, and the second electrode EL2 may surround the first electrode EL1, but not limited thereto. In other words, a region HR may be enclosed by the second electrode EL2, and the first electrode EL1 may be disposed in the region HR. In such condition, as shown in FIG. 1, in a cross-sectional view of the electronic device ED, the second electrode EL2 may be located at two sides of the first electrode EL1. The above-mentioned solid pattern of the first electrode EL1 may for example include circle, rectangle, polygon or other suitable shapes. For example, in the present embodiment, the first electrode EL1 may be circular. The above-mentioned ring-shaped second electrode EL2 may for example include a ring pattern, a frame pattern or other suitable patterns. Through the pattern design of the above-mentioned electrodes, the first electrode EL1 and the second electrode EL2 may substantially have symmetrical structures, such that the bonding between the electronic unit EU and the interconnection elements IE (shown in FIG. 3A) may be improved. Specifically, even if the electronic unit EU is rotated during the fluid transfer process and is not disposed in the recess RS in a specific direction, the possibility that the interconnection elements IE overlap the first electrode EL1 and the second electrode EL2 may increase by making the first electrode EL1 and the second electrode EL2 have symmetrical structures, thereby reducing abnormal electrical connection of the electronic unit EU. For example, as shown in FIG. 3A, even if the electronic unit EU in the recess RS rotates, the interconnection elements IE may still correspond to the first electrode EL1 and the second electrode EL2. It should be noted that the pattern design of the electrodes is described by taking the electronic unit EU having two electrodes as an example in the present embodiment, but the present disclosure is not limited thereto. In some embodiments, the electronic unit EU may further include another electrode including any suitable ring shape, and the another electrode may surround the first electrode EL1 and the second electrode EL2.

The design of the width of the electrodes of the electronic unit EU of the present embodiment will be described in the following. In the present embodiment, in the top view direction of the electronic device ED, the recess RS may be circular and have a radius R1, and the electronic unit EU disposed in the recess RS may be square and have a side length SL. The electrodes of the electronic unit EU (including the first electrode EL1 and the second electrode EL2) may have a width W1. Specifically, although it is not shown in FIG. 3A, the first electrode EL1 may have the width W1, wherein the width W1 may be defined as the maximum distance in the pattern of the first electrode EL1, but not limited thereto. In some embodiments, when the pattern of the first electrode EL1 is a circle (as shown in FIG. 3A), the width W1 of the first electrode EL1 may be the diameter of the circle. In some embodiments, when the pattern of the first electrode EL1 is a rectangle, the width W1 of the first electrode EL1 may be the length of the diagonal of the rectangle. The width W1 of the second electrode EL2 may be defined as the ring width of the ring shape, but not limited thereto. According to the present embodiment, the width W1 of the electrodes of the electronic unit EU and the side length SL of the electronic unit EU may satisfy the following equation (2):

$$0 < W 1 < \frac{SL}{2 N 1 - 1} \qquad ( 2 )$$

Wherein N1 is the number of the signal connecting points of the electronic unit EU mentioned above, and N1 may for example be 2 in the present embodiment. In other words, the width W1 of the electrodes of the electronic unit EU may be lower than SL/3 in the present embodiment, but not limited thereto. Specifically, as shown in FIG. 3A, the length of a side of the electronic unit EU (that is, the side length SL) should at least be greater than the width W1 of the first electrode EL1 and two times the width W1 of the second electrode EL2. In such condition, it can be inferred that the side length SL should at least be greater than 2*(N1−1)+1 times the width W1 when the electronic unit EU includes N1 signal connecting points, and therefore, the relation between the width W1 and the side length SL shown in the equation (2) may be obtained. In a comparative example, when the width W1 of the electrodes of the electronic unit EU is greater than SL/(2N1−1), the electrodes may contact with each other, thereby causing short circuit.

In the present embodiment, the maximum of the side length SL of an electronic unit EU may be determined according to the size of the recess RS where the electronic unit EU is located. Specifically, as shown in FIG. 3A, in the present embodiment, the recess RS may have the radius R1, and in such condition, the maximum of the side length SL of the electronic unit EU may be \sqrt{2}R1. Therefore, the relation between the width W1 of the electrodes of the electronic unit EU and the radius R1 of the recess RS may be obtained through the equation (2), which is shown in the following equation (3):

$$0 < W 1 < \frac{\sqrt{2} R 1}{2 N 1 - 1} \qquad ( 3 )$$

Specifically, after the size (for example, the radius R1) of a recess RS is confirmed, the width W1 of the electrodes of the electronic unit EU disposed in the recess RS may be designed according to the size of the recess RS, such that the width W1 is located in the above-mentioned range. Therefore, the condition that the electrical function of the electronic unit EU is affected due to the excessive width of the electrodes may be reduced.

In some embodiments, the width W1 of the electrodes of the electronic unit EU and the radius R1 of the recess RS may satisfy the following equation (4):

$$0 < W 1 < \frac{\sqrt{2} R 1}{4 N 1 - 2} \qquad ( 4 )$$

Specifically, the range of the width W1 of the electrodes of the electronic unit EU may be designed to be half of the range shown in the equation (3) shown above. Through the width design above, the projection of the bottom of the interconnection elements IE of the conductive layer ML on the electronic unit EU (as shown in FIG. 3A) may be close to the centers of the first electrode EL1 and the second electrode EL2, or the disposition position of the interconnection elements IE may correspond to the position close to the centers of the first electrode EL1 and the second electrode EL2. Therefore, the electrical connection between the electronic unit EU and the interconnection elements IE may be improved.

Referring to FIG. 3A as well as FIG. 1, as mentioned above, in the present embodiment, the conductive layer ML may be electrically connected to the first electrode EL1 of the electronic unit EU through the first via V11 (or through the interconnection element IE1 disposed in the first via V11), and the conductive layer ML may be electrically connected to the second electrode EL2 of the electronic unit EU through the second via V12 (or through the interconnection element IE2 disposed in the second via V12) adjacent to the first via V11. In the present embodiment, in the top view direction of the electronic device ED, a minimum distance W2 may be included between the first via V11 and the second via V12. The minimum distance W2 may be defined as the minimum distance between the bottom of the first via V11 and the bottom of the second via V12 in the top view direction of the electronic device ED. The minimum distance W2 between the first via V11 and the second via V12 may for example be shown in FIG. 1 and FIG. 3A. In another aspect, the minimum distance W2 of the present embodiment may also be defined as the minimum distance between the interconnection element IE1 disposed in the first via V11 and the interconnection element IE2 disposed in the second via V12 in the top view direction of the electronic device ED. According to the present embodiment, the minimum distance W2 may satisfy the following equation (5):

$$0 < W 2 < \frac{2 \sqrt{2} R 1}{2 N 1 - 1} \qquad ( 5 )$$

Wherein R1 is the radius of the recess RS, and N1 is the number of the signal connecting points of the electronic unit EU. Specifically, the range of the minimum distance W2 between the first via V11 and the second via V12 may be two times the range of the width W1 shown in the equation (3) above. By making the minimum distance W2 located in the above-mentioned range, the poor bonding between the interconnection element IE1 and the first electrode EL1 (or the interconnection element IE2 and the second electrode EL2) may be reduced, thereby improving the yield of the electronic device ED. In a comparative example, when the minimum distance W2 is 0, the interconnection element IE1 may contact the interconnection element IE2, thereby causing short circuit. In another comparative example, when the minimum distance W2 is greater than the range shown in the equation (5), the distance between the first via V11 and the second via V12 may be too great (for example, greater than two times of the width W1 of the electrodes of the electronic unit EU). In such condition, the interconnection elements IE of the conductive layer ML may not contact the electrodes of the electronic unit EU, thereby causing electrical abnormality.

Referring to FIG. 3B, FIG. 3B schematically illustrates top views of the electronic unit and the recess according to a variant embodiment of the first embodiment of the present disclosure. In the present variant embodiment, the side length SL1 of the electronic unit EU may be lower than the side length SL of the electronic unit EU shown in FIG. 3A. Specifically, the side length SL1 of the electronic unit EU of the present variant embodiment may be 1/k times the side length SL of the electronic unit EU shown in FIG. 3A (that is, SL1=SL/k), wherein k is greater than 1. In some embodiments, k may be greater than 1 and lower than or equal to 2, that is, SL/2≤SL1<SL, but not limited thereto. In such condition, as shown in FIG. 3B, the recess RS may have a center CE1, the electronic unit EU may have a center CE2, and the center CE2 of the electronic unit EU may be offset from the center CE1 of the recess RS in a offset distance DS1. In addition, a minimum distance DS2 may be included between the first electrode EL1 and the second electrode EL2 of the electronic unit EU in the direction of the offset distance DS1. According to the present variant embodiment, the offset distance DS1 may be expressed in the radius R1 and the side length SL1 which is shown in the equation (A) below:

$$DS 1 = \sqrt{R {1}^{2} - {( \frac{S L 1}{2} )}^{2}} - \frac{S L 1}{2} \qquad ( A )$$

Wherein the side length SL1 may be 1/k times the side length SL of the electronic unit EU shown in FIG. 3A, that is, the side length SL1 may be \sqrt{2}R1/k. By substituting the above-mentioned value into the equation (A), the offset distance DS1 may be shown in the equation (B) below:

$$DS 1 = \frac{( \sqrt{4 {k}^{2} - 2} - \sqrt{2} )}{2 k} R 1 \qquad ( B )$$

In addition, in the present variant embodiment, the center CE2 of the electronic unit EU may be the center of the first electrode EL1 (for example, the center of the circular first electrode EL1), and the first electrode EL1 may have the width W1. In such condition, the minimum distance DS2 between the first electrode EL1 and the second electrode EL2 may be expressed in the following equation (C):

$$DS 2 = \frac{\sqrt{2}}{2 k} R 1 - \frac{3}{2} W 1 \qquad ( C )$$

According to the present variant embodiment, the offset distance DS1 may be greater than 0 and lower than half of the sum of the width W1 and the minimum distance DS2, that is, as shown in the equation (D) below:

$$0 < DS 1 < \frac{W 1 + DS 2}{2} \qquad ( D )$$

Through the above-mentioned design, the possibility of abnormal electrical connection due to the excessive offset distance DS1 may be reduced. The following equation (E) may be obtained by combining the equation (C) and the equation (D) above.

$$0 < DS 1 < \frac{\sqrt{2}}{4 k} R 1 - \frac{1}{4} W 1 \qquad ( E )$$

After that, by combining the equation (E) and the equation (B), the range of the width W1 may be obtained, which is shown in the following equation (F):

$$0 < W 1 < \frac{( 3 \sqrt{2} - 2 \sqrt{4 {k}^{2} - 2} )}{k} R 1 \qquad ( F )$$

In other words, by making the width W1 of the electrodes (including the first electrode EL1 and the second electrode EL2) of the electronic unit EU located in the range shown in the equation (F) above, the electrical connection between the electronic unit EU and other electronic elements (such as the interconnection element IE) may be improved.

In some embodiments, the offset distance DS1 may be greater than 0 and lower than the sum of the width W1 and the minimum distance DS2, that is, as shown in the equation (G):

$$0 < DS 1 < W 1 + DS 2 \qquad ( G )$$

In such condition, the range of the width W1 may be obtained through the method mentioned above, which is shown in the equation (H) in the following:

$$0 < W 1 < \frac{2 ( 3 \sqrt{2} - 2 \sqrt{4 {k}^{2} - 2} )}{k} R 1 \qquad ( H )$$

In short, in the present variant embodiment, the electronic unit EU may be disposed at any suitable position in the recess RS and may be offset from the center CE1 of the recess RS, wherein the abnormal electrical connection of the electronic unit EU due to the excessive offset distance DS1 may be reduced through the above-mentioned design of the range of the width W1 of the electrodes of the electronic unit EU.

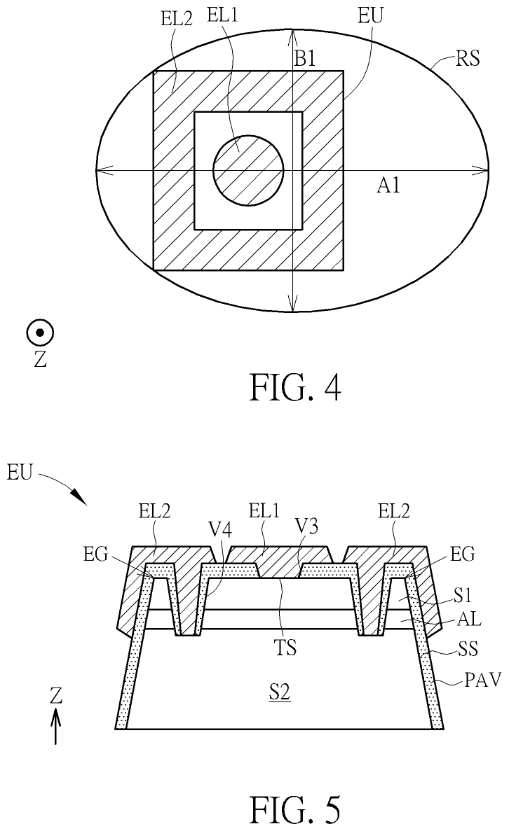

Referring to FIG. 4, FIG. 4 schematically illustrates top views of the electronic unit and the recess according to another variant embodiment of the first embodiment of the present disclosure. In the present variant embodiment, the shape of the recess RS may be an oval or any suitable shape similar to the oval in the top view direction of the electronic device ED. In such condition, the recess RS may have a major axis and a minor axis, wherein the major axis of the recess RS may have a length Al, and the minor axis of the recess RS may have a length B1. In the present variant embodiment, the radius R1 of the recess RS shown in the equation (3) to the equation (5) above may be replaced by the length Al and the length B1 in the present variant embodiment. Specifically, the radius R1 may be obtained according to the following equation (6):

$$R 1 = ( R 1 + B 1 ) / 4 \qquad ( 6 )$$

In other words, the radius R1 of the recess RS of the present variant embodiment may be defined according to the length Al and the length B1, and the sizes of the elements may be design according to the equation (3) to the equation (5).

According to the present embodiment, the electronic units EU of the electronic device ED may be transferred to be in the recesses RS of the substrate SB through the fluid transfer process, and the influence of the randomness of the distribution of the electronic units EU in the recesses RS on the electrical connection between the electronic units EU and the conductive layer ML may be reduced under the condition of the fixed configuration of the conductive layer ML through the above-mentioned size designs of the electronic unit EU and the recess RS, the pattern design and the width design of the electrodes of the electronic unit EU, and the design of the distance between the interconnection elements, thereby improving the yield of the electronic device ED. It should be noted that the above-mentioned designs may be applied to other embodiments that the electronic device ED includes electronic units EU of other types or other embodiments that the electronic unit EU includes more than two signal connecting points, and the present disclosure is not limited thereto.

The structural feature of the electronic unit EU will be detailed in the following. It should be noted that the structure of the electronic unit EU is described by taking the inorganic light emitting diode as an example of the electronic unit EU, but the present disclosure is not limited thereto. The structural feature of the electronic unit EU described in the following may be applied to any suitable embodiment that the electronic unit EU includes elements of other types.

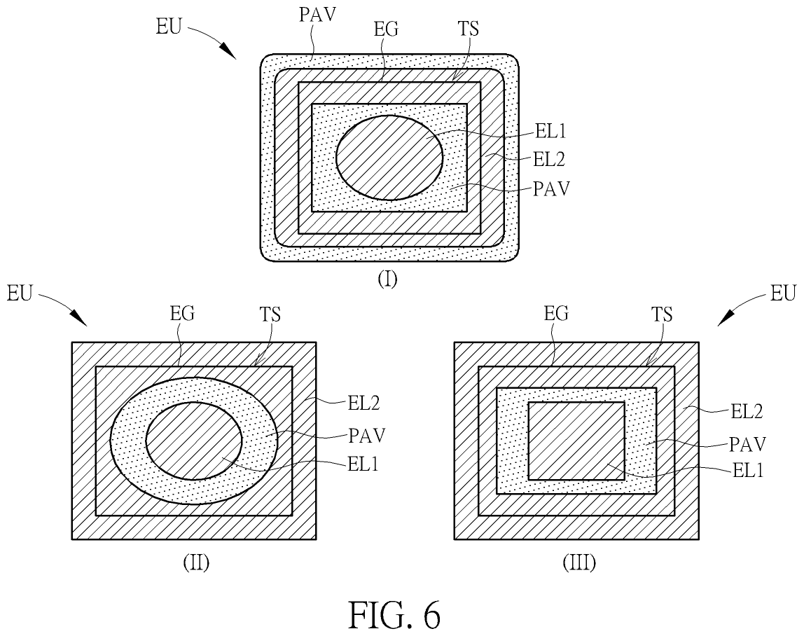

Referring to FIG. 5 and FIG. 6, FIG. 5 schematically illustrates a cross-sectional view of an electronic unit according to a second embodiment of the present disclosure, and FIG. 6 schematically illustrates a top view of the electronic unit according to the second embodiment of the present disclosure. Similar to the above-mentioned first embodiment, the electronic unit EU of the present embodiment may include the first semiconductor layer S1, the second semiconductor layer S2, the active layer AL disposed between the first semiconductor layer S1 and the second semiconductor layer S2, the first electrode EL1 electrically connected to the first semiconductor layer S1, and the second electrode EL2 electrically connected to the second semiconductor layer S2. The first electrode EL1 and the second electrode EL2 are disposed at the same side of the electronic unit EU. Specifically, the first electrode EL1 and the second electrode EL2 may be disposed at a side of the first semiconductor layer S1 opposite to the active layer AL, but not limited thereto. The electronic unit EU may further include a passivation layer PAV, wherein the passivation layer PAV may be disposed along the top surface TS and the side surface SS of the electronic unit EU. In the present embodiment, the top surface TS of the electronic unit EU may be defined as the top surface of the first semiconductor layer S1 or the surface of the first semiconductor layer S1 opposite to the active layer AL, but not limited thereto. In some embodiments, the second semiconductor layer S2 may be disposed on the first semiconductor layer S1, and the top surface TS of the electronic unit EU may be defined as the top surface of the second semiconductor layer S2. The side surface SS of the electronic unit EU may be defined as the side surface of the first semiconductor layer S1, the side surface of the second semiconductor layer S2 and the side surface of the active layer AL. The first electrode EL1 is disposed on the passivation layer PAV. The electronic device ED may include a via V3, wherein the via V3 may be formed by removing a portion of the passivation layer PAV. The via V3 may penetrate through the passivation layer PAV and expose the first semiconductor layer S1, and a portion of the first electrode EL1 may be filled into the via V3 and contact the first semiconductor layer S1, thereby being electrically connected to the first semiconductor layer S1. The electronic device ED may further include a via V4, wherein the via V4 may be formed by removing a portion of the first semiconductor layer S1, a portion of the active layer AL and a portion of the second semiconductor layer S2. The via V4 may expose the second semiconductor layer S2, and a portion of the second electrode EL2 may be filled into the via V4 and contact the second semiconductor layer S2, thereby being electrically connected to the second semiconductor layer S2. In addition, the passivation layer PAV may be filled into the via V4 and disposed along the sidewall of the via V4. Specifically, the passivation layer PAV may be disposed along the sidewall of the via V4 at first, and then the second electrode EL2 may be filled into the via V4. Therefore, the passivation layer PAV may electrically insulate the second electrode EL2 and the first semiconductor layer S1. In such condition, in a cross-sectional view of the electronic unit EU, the portion of the second electrode EL2 located in the via V4 may be sandwiched between the passivation layer PAV. It should be noted that the structure of the electronic unit EU mentioned above is exemplary, and the present disclosure is not limited thereto.

According to the present embodiment, as shown in FIG. 5 and FIG. 6, in the top view direction of the electronic device ED, the top surface TS of the electronic unit EU may have an edge EG, and the second electrode EL2 may protrude from the edge EG of the top surface TS. Specifically, “the second electrode EL2 protrudes from the edge EG of the top surface TS in the top view direction of the electronic device ED” mentioned in the present embodiment may include any suitable embodiment that the second electrode EL2 extends from the top surface TS of the electronic unit EU to the side surface SS of the electronic unit EU. For example, as shown in FIG. 5, the second electrode EL2 of the electronic unit EU may extend from the top surface TS of the electronic unit EU to the side surface SS of the electronic unit EU. In other words, the second electrode EL2 may be disposed on the top surface TS and the side surface SS of the electronic unit EU. In such condition, in the top view direction of the electronic device ED, the size of the projected shape of the top surface TS of the electronic unit EU may be lower than the size of the projected shape of the second electrode EL2 of the electronic unit EU. It should be noted that “the width W1 of the second electrode EL2” mentioned above may be the sum of the width of a portion of the second electrode EL2 on the top surface TS and the width of another portion of the second electrode EL2 on the side surface SS, but not limited thereto. By making the second electrode EL2 further extend to the side surface SS of the electronic unit EU, the effective area of the second electrode EL2 may increase, thereby increasing the possibility that the interconnection element IE (for example, the interconnection element IE2) of the conductive layer ML is electrically connected to the second electrode EL2.

FIG. 6 for example shows multiple examples of the structure of the electronic unit EU in the top view direction of the electronic device ED. In the examples shown in FIG. 6, in the top view direction of the electronic device ED, the second electrode EL2 may include any suitable ring structure and surround the first electrode EL1. In example (I), the second electrode EL2 may extend from the top surface TS to the side surface SS but not completely cover the side surface SS. In such condition, in the top view direction of the electronic device ED, a portion of the passivation layer PAV may be exposed. In addition, in example (I), the second electrode EL2 may substantially have a frame shape in the top view direction of the electronic device ED, that is, the inner edge and the outer edge of the second electrode EL2 may substantially be rectangular. Moreover, according to some embodiments, as shown in example (I), the second electrode EL2 may have a round-corner structure or other suitable non-sharp-corner structures. Therefore, the possibility of damage of the second electrode EL2 due to collision between different second electrodes EL2 during the transfer process of the electronic units EU may be reduced. The top view structure of the second electrode EL2 shown in example (I) may for example correspond to the cross-sectional structure shown in FIG. 5, but not limited thereto. In example (II), the second electrode EL2 may extend from the top surface TS to the side surface SS and completely cover the side surface SS. In other words, the portion of the passivation layer PAV on the side surface SS may be completely covered by the second electrode EL2 and is not exposed. In addition, in example (II), the outer edge of the ring structure of the second electrode EL2 may substantially be aligned with the outer edge of the electronic unit EU and for example be rectangular, and the inner edge of the ring structure of the second electrode EL2 may be a circle or an oval, but not limited thereto. In example (III), similar to the example (II), the second electrode EL2 may completely cover the side surface SS, that is, the portion of the passivation layer PAV on the side surface SS may not be exposed. In addition, in example (III), the second electrode EL2 may have a frame shape in the top view direction of the electronic device ED, that is, the inner edge and the outer edge of the second electrode EL2 may be rectangular, wherein the outer edge of the second electrode EL2 may substantially be aligned with the outer edge of the electronic unit EU. It should be noted that the top view structure of the electronic unit EU of the present embodiment is not limited to what is shown in FIG. 6 and may include any suitable structure.

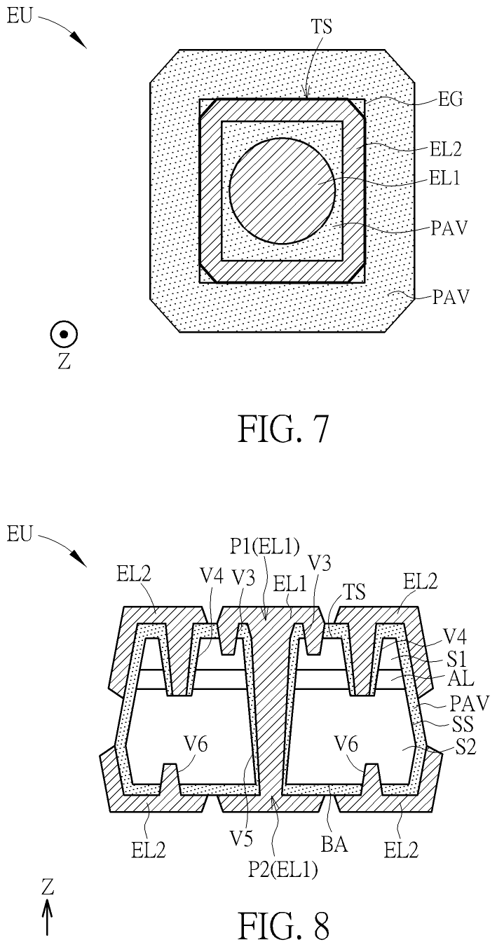

Referring to FIG. 7, FIG. 7 schematically illustrates a top view of an electronic unit according to a variant embodiment of the second embodiment of the present disclosure. One of the main differences between the electronic unit EU of the present variant embodiment and the electronic unit EU shown in FIG. 5 and FIG. 6 is the design of the second electrode EL2. According to the present variant embodiment, as shown in FIG. 7, in the top view direction of the electronic device ED, the outer edge of the second electrode EL2 may substantially be aligned with the edge EG of the top surface TS of the electronic unit EU in the top view direction of the electronic device ED, or the outer edge of the second electrode EL2 may overlap the edge EG. In other words, the second electrode EL2 may not protrude from the edge EG of the top surface TS. In such condition, the second electrode EL2 may not be disposed on the side surface SS of the electronic unit EU, or the portion of the passivation layer PAV disposed on the side surface SS may not be covered by the second electrode EL2. In addition, as shown in FIG. 7, the second electrode EL2 and the electronic unit EU of the present variant embodiment may include a chamfering structure, but not limited thereto. Therefore, the possibility of damage of the second electrode EL2 or the electronic unit EU due to collision between different second electrodes EL2 and different electronic units EU during the transfer process of the electronic units EU may be reduced. It should be noted that the shapes of the patterns of the first electrode EL1 and the second electrode EL2 of the present variant embodiment may refer to the contents in the above-mentioned embodiments, which are not limited to what is shown in FIG. 7.

Other embodiments of the structure of the electronic unit EU will be described in the following. In order to simplify the description, the same elements or layers in the following embodiments would be labeled with the same symbol, and the features thereof will not be redundantly described. The differences between the embodiments will be detailed in the following.

Referring to FIG. 8, FIG. 8 schematically illustrates a cross-sectional view of an electronic unit according to a third embodiment of the present disclosure. According to the present embodiment, the first electrode EL1 and the second electrode EL2 of the electronic unit EU may further be disposed at a side of the second semiconductor layer S2 opposite to the active layer AL. In other words, the first electrode EL1 and the second electrode EL2 may be disposed at two sides of the electronic unit EU. Specifically, as shown in FIG. 8, the first electrode EL1 may include a portion P1 disposed at a side of the top surface TS of the electronic unit EU and a portion P2 disposed at a side of the bottom surface BA of the electronic unit EU, wherein the portion P1 and the portion P2 may be electrically connected to each other through a via V5. The bottom surface BA of the electronic unit EU may for example be defined as the bottom surface of the second semiconductor layer S2 or the surface of the second semiconductor layer S2 opposite to the active layer AL. The via V5 may penetrate through the first semiconductor layer S1, the active layer AL and the second semiconductor layer S2, such that the portion P1 and the portion P2 of the first electrode EL1 may be filled into the via V5 and be electrically connected to each other. The passivation layer PAV may be filled into the via V5 and be disposed along the sidewall of the via V5. Therefore, the first electrode EL1 and the second semiconductor layer S2 may be electrically insulated from each other through the passivation layer PA. The first electrode EL1 may be electrically connected to the first semiconductor layer S1 through the via V3, and the detail thereof may refer to the contents above, which will not be redundantly described. Compared with the embodiments above, the via V3 of the present embodiment may be formed by further removing a portion of the first semiconductor layer S1, but not limited thereto. The second electrode EL2 disposed at a side of the top surface TS may be electrically connected to the second semiconductor layer S2 through the via V4, and the detail thereof may refer to the contents mentioned above, which will not be redundantly described. In addition, the electronic unit EU of the present embodiment may further include a second electrode EL2 disposed at a side of the bottom surface BA, wherein the second electrode EL2 may be electrically connected to the second semiconductor layer S2 through a via V6. The via V6 may be formed by removing a portion of the passivation layer PAV and a portion of the second semiconductor layer S2, but not limited thereto. In some embodiments, the via V6 may be formed by removing a portion of the passivation layer PAV, and the second semiconductor layer S2 may be exposed. In the present embodiment, the passivation layer PVA may further be disposed corresponding to the bottom surface BA of the electronic unit EU, such that the first electrode EL1 and the second electrode EL2 may be disposed at a side of the bottom surface BA. The pattern of the first electrode EL1 (or the second electrode EL2) disposed at a side of the bottom surface BA may for example be the same as the pattern of the first electrode EL1 (or the second electrode EL2) disposed at a side of the top surface TS, but not limited thereto. According to the present embodiment, by making the first electrode EL1 and the second electrode EL2 disposed at two sides of the electronic unit EU, the conductive layer ML may still contact the first electrode EL1 and the second electrode EL2 even if the electronic unit EU is flipped during the fluid transfer process. Therefore, the electrical connection between the first electrode EL1 (and the second electrode EL2) and the conductive layer ML may be improved.

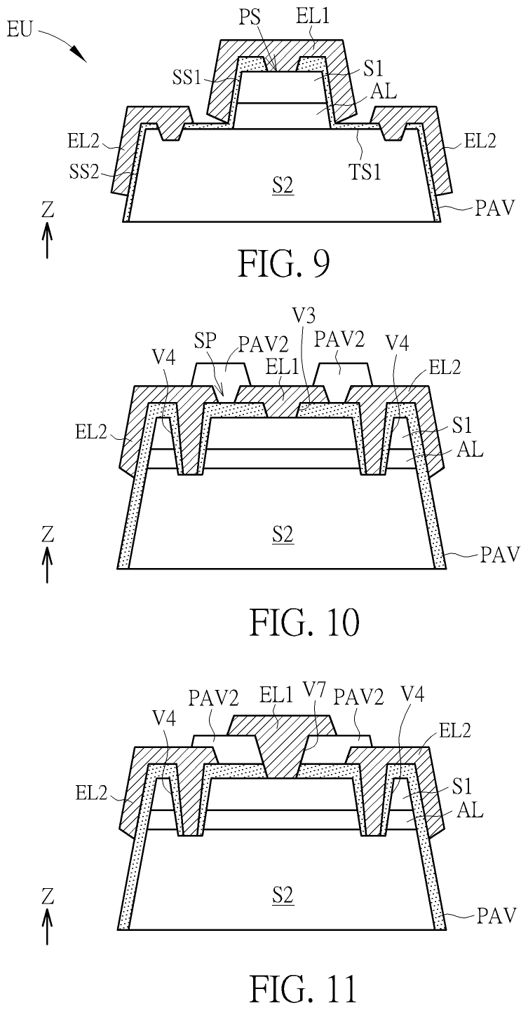

Referring to FIG. 9, FIG. 9 schematically illustrates a cross-sectional view of an electronic unit according to a fourth embodiment of the present disclosure. According to the present embodiment, the manufacturing process of the electronic unit EU may include a MESA process. Specifically, as shown in FIG. 9, a portion of the active layer AL and a portion of the first semiconductor layer S1 may be removed through an etching process, such that the active layer AL and the first semiconductor layer S1 may form a platform structure PS, wherein the platform structure PS is disposed on the second semiconductor layer S2. A portion of the top surface TS1 of the second semiconductor layer S2 may not be covered by the platform structure PS, that is, the platform structure PS may not completely cover the top surface TS1 of the second semiconductor layer S2. In such condition, the passivation layer PAV may further be disposed on the portion of the top surface TS1 of the second semiconductor layer S2 not covered by the platform structure PS. According to the present embodiment, as shown in FIG. 9, by making the structure of the first semiconductor layer S1 be a platform shape, the first electrode EL1 may further be disposed on the side surface SS1 of the first semiconductor layer S1 in addition to being disposed on the top surface TS, that is, the first electrode EL1 may extend from the top surface TS to the side surface SS1. In some embodiments, the first electrode EL1 may further extend on the side surface (not labeled) of the active layer AL. Through the designs above, the effective area of the first electrode EL1 may increase, thereby increasing the possibility that the interconnection element IE (for example, the interconnection element IE1) of the conductive layer ML is electrically connected to the first electrode EL1. The first electrode EL1 may be electrically connected to the first semiconductor layer S1 through a via (not labeled). In addition, in the present embodiment, the second electrode EL2 may be disposed on the portion of the top surface TS1 of the second semiconductor layer S2 not covered by the platform structure PS and/or disposed on the side surface SS2, and the second electrode EL2 may be electrically connected to the second semiconductor layer S2 through a via (not labeled), but not limited thereto. In some embodiments, the second electrode EL2 may not be disposed on the side surface SS2 of the second semiconductor layer S2.

Referring to FIG. 10, FIG. 10 schematically illustrates a cross-sectional view of an electronic unit according to a fifth embodiment of the present disclosure. According to the present embodiment, the electronic unit EU may further include a passivation layer PAV2 disposed between the first electrode EL1 and the second electrode EL2. Specifically, as shown in FIG. 10, the passivation layer PAV2 may be disposed corresponding to a gap SP between the first electrode EL1 and the second electrode EL2. Return to FIG. 3A, in the top view direction of the electronic device ED, the gap SP between the first electrode EL1 and the second electrode EL2 may for example correspond to the remaining region of the region HR except for the region occupied by the first electrode EL1, but not limited thereto. In detail, after the first electrode EL1 and the second electrode EL2 are formed, the passivation layer PAV2 may be disposed on the first electrode EL1 and the second electrode EL2 at a position corresponding to the gap SP, wherein the passivation layer PAV2 may be filled into the gap SP and thereby being disposed between the first electrode LE1 and the second electrode EL2. In such condition, the passivation layer PAV2 may have a ring structure, but not limited thereto. The passivation layer PAV2 may be used to electrically insulate the first electrode EL1 and the second electrode EL2, such that the possibility that the first electrode EL1 and the second electrode EL2 are electrically connected to each other may be reduced. The structural features of other elements of the electronic unit EU may refer to FIG. 5 and the contents above, and will not be redundantly described.

Referring to FIG. 11, FIG. 11 schematically illustrates a cross-sectional view of an electronic unit according to a sixth embodiment of the present disclosure. One of the main differences between the electronic unit EU of the present embodiment and the electronic unit EU shown in FIG. 10 is the design of the passivation layer PAV2. According to the present embodiment, during the manufacturing process of the electronic unit EU, after the second electrode EL2 is formed, the passivation layer PAV2 may be disposed at the position corresponding to the region HR (as shown in FIG. 3A). The passivation layer PAV2 may be filled into the recess (not labeled) formed (or enclosed) by the second electrode EL2. The passivation layer PAV2 may partially cover the second electrode EL2 or be disposed on the second electrode EL2. After that, the first electrode EL1 may be formed on the passivation layer PAV2. In other words, in the present embodiment, the passivation layer PAV2 may be disposed on the second electrode EL2, and the first electrode EL1 may be disposed on the passivation layer PAV2, but not limited thereto. Therefore, the passivation layer PAV2 may be disposed between the first electrode EL1 and the second electrode EL2 and electrically insulate the first electrode EL1 and the second electrode EL2. In the present embodiment, the first electrode EL1 may be electrically connected to the first semiconductor layer S1 through a via V7, wherein the via V7 may be formed by removing a portion of the passivation layer PAV2 and a portion of the passivation layer PAV. In some embodiments, the via V7 may be formed by further removing a portion of the first semiconductor layer S1. The structural features of other elements of the electronic unit EU may refer to FIG. 5 and the contents above, and will not be redundantly described.

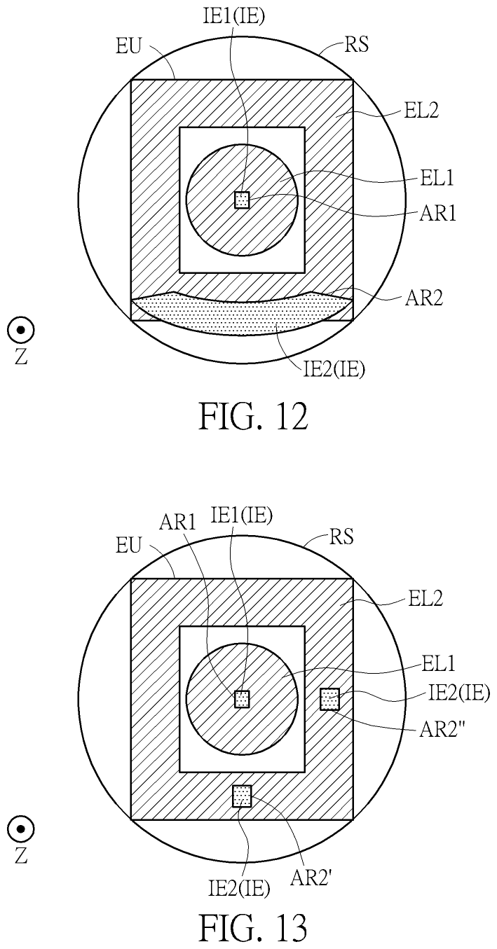

Referring to FIG. 12 and FIG. 13, FIG. 12 schematically illustrates top views of the electronic unit and the recess according to a seventh embodiment of the present disclosure, and FIG. 13 schematically illustrates top views of the electronic unit and the recess according to a variant embodiment of the seventh embodiment of the present disclosure. According to the present embodiment, in the top view direction of the electronic device ED, the size of the interconnection element IE1 electrically connected to the first electrode EL1 may be lower than the size of the interconnection element IE2 electrically connected to the second electrode EL2. The size of the interconnection element IE1 (or the interconnection element IE2) may be the area of the interconnection element IE1 (or the interconnection element IE2), but not limited thereto. For example, in the present embodiment, the area of the interconnection element IE1 may be lower than the area of the interconnection element IE2. “The area of the interconnection element IE1 (or the interconnection element IE2)” described herein may be defined as the area of the projection of the interconnection element IE1 (or the interconnection element IE2) on a plane perpendicular to the top view direction of the electronic device ED, but not limited thereto. For example, as shown in FIG. 12, in the top view direction of the electronic device ED, the interconnection element IE1 may have an area AR1, and the interconnection element IE2 may have an area AR2, wherein the area AR2 may be greater than the area AR1. It should be noted that the area AR1 of the interconnection element IE1 mentioned above may also be the area of the first via V11, and the area AR2 of the interconnection element IE2 may also be the area of the second via V12. In other words, in the present embodiment, the conductive layer ML of the electronic device ED may be electrically connected to the first electrode EL1 through the first via V11 and be electrically connected to the second electrode EL2 through the second via V12, and in the top view direction of the electronic device ED, the area of the second via V12 (that is, the area AR2) may be greater than the area of the first via V11 (that is, the area AR1). In some embodiments, the size of the interconnection element IE1 (or the interconnection element IE2) mentioned above may be the width of the interconnection element IE1 (or the interconnection element IE2), that is, the width of the interconnection element IE1 may be lower than the width of the interconnection element IE2. “The width of the interconnection element IE1 (or the interconnection element IE2)” described herein may be defined as the width of the projection of the bottom of the interconnection element IE1 (or the interconnection element IE2) on a plane perpendicular to the top view direction of the electronic device ED in a cross-sectional view (for example, FIG. 1, but not limited thereto) of the electronic device ED, but not limited thereto. For example, as shown in FIG. 1, the interconnection element IE1 may have a width L1, and the interconnection element IE2 may have a width L2, wherein the width L2 may be greater than the width L1. It should be noted that the width L1 of the interconnection element IE1 may also be the width of the first via V11, and the width L2 of the interconnection element IE2 may also be the width of the second via V12, that is, the width of the first via V11 is lower than the width of the second via V12. According to the present embodiment, by making the area (or the width) of the second via V12 (or the interconnection element IE2) greater than the area (or the width) of the first via V11 (or the interconnection element IE1), the short circuit due to contact between the interconnection element IE1 and the interconnection element IE2 may be reduced, thereby improving the reliability of the electronic device ED.

In some embodiments, the conductive layer ML may include a plurality of interconnection elements IE2 electrically connected to the second electrode EL2, that is, a second electrode EL2 may correspond to a plurality of interconnection elements IE2, wherein the sum of the areas of these interconnection elements IE2 may be greater than the area of the interconnection element IE1 electrically connected to the first electrode EL1. For example, as shown in FIG. 13, the conductive layer ML may include two interconnection elements IE2 electrically connected to the second electrode EL2, and the two interconnection elements IE2 may respectively have an area AR2′ and an area AR2″, wherein the sum of the area AR2′ and the area AR2″ may be greater than the area AR1 of the interconnection element IE1 electrically connected to the first electrode EL1. The area AR2′ and the area AR2″ may be the same or different, the present disclosure is not limited thereto.

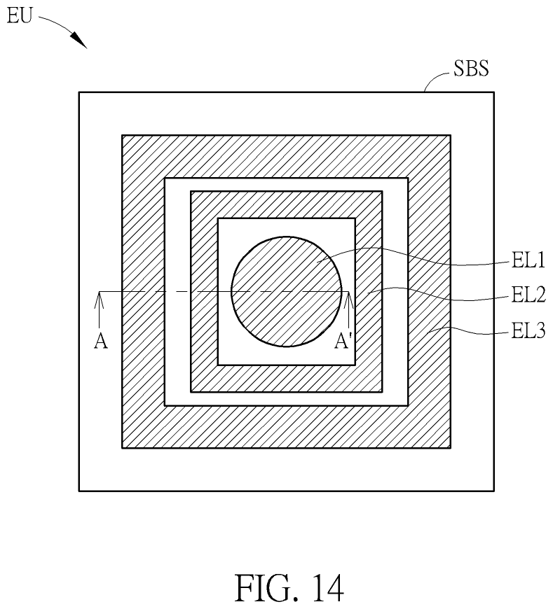

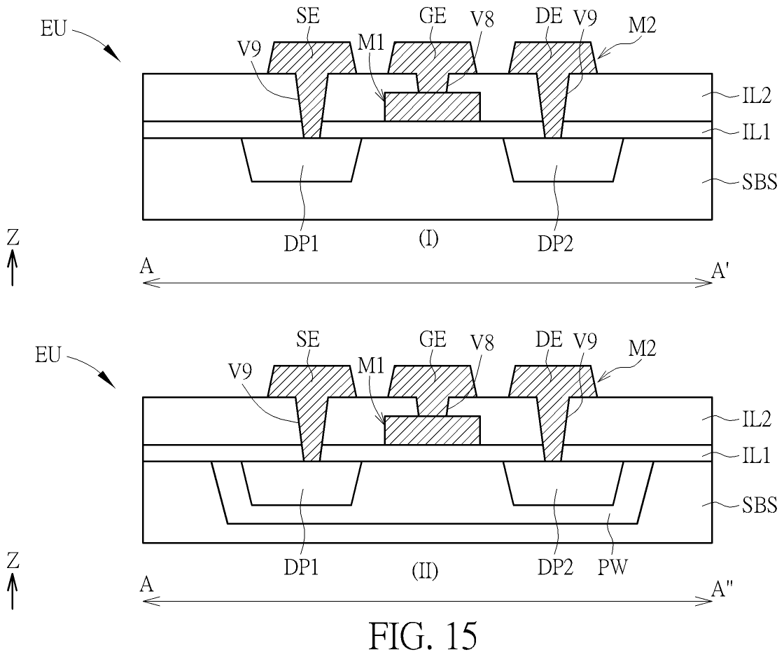

Referring to FIG. 14 and FIG. 15, FIG. 14 schematically illustrates a top view of an electronic unit according to an eighth embodiment of the present disclosure, and FIG. 15 schematically illustrates a cross-sectional view of the electronic unit according to the eighth embodiment of the present disclosure. In the present embodiment, the electronic unit EU may include a metal-oxide-semiconductor field-effect transistor (MOSFET). FIG. 15 shows examples of the electronic unit EU of the present embodiment. For example, in example (I) shown in FIG. 15, the electronic unit EU may include a p-type MOSFET (PMOS) element. In detail, as shown in example (I), the electronic unit EU may include a substrate SBS, an insulating layer ILL disposed on the substrate SBS, a conductive layer M1 disposed on the insulating layer IL1, an insulating layer IL2 disposed on the insulating layer IL1 and covering the conductive layer M1, and a conductive layer M2 disposed on the insulating layer IL2, but not limited thereto. The substrate SBS may include a semiconductor substrate, wherein the semiconductor substrate may include n-type semiconductor materials. The substrate SBS may have a doped region DP1 and a doped region DP2, wherein the doped region DP1 and the doped region DP2 may be a p-type doped region. A portion of the conductive layer M2 may be electrically connected to the conductive layer M1 through a via V8, and the conductive layer M1 and the portion of the conductive layer M2 electrically connected to the conductive layer M1 may form the gate electrode GE. A portion of the conductive layer M2 may be electrically connected to the doped region DP1 through a via V9, and the portion of the conductive layer M2 may form one of the source electrode SE and the drain electrode DE (for example, the source electrode SE in FIG. 15, but not limited thereto); another portion of the conductive layer M2 may be electrically connected to the doped region DP2 through another via V9, and the another portion of the conductive layer M2 may form another one of the source electrode SE and the drain electrode DE (for example, the drain electrode DE in FIG. 15, but not limited thereto). The via V9 may be formed by removing a portion of the insulating layer IL1 and a portion of the insulating layer IL2, and the doped region DP1 and the doped region DP2 may be exposed. The insulating layer IL1 and the insulating layer IL2 may include any suitable insulating material. The insulating layer IL1 may serve as the gate insulating layer. The conductive layer M1 and the conductive layer M2 may include any suitable conductive material, such as metals, but not limited thereto. In addition, in example (II) of FIG. 15, the electronic unit EU may include a n-type MOSFET (NMOS) element. In such condition, the substrate SBS of the electronic unit EU may further include a p-type well PW, and the doped region DP1 and the doped region DP2 may be formed in the p-type well PW, wherein the doped region DP1 and the doped region DP2 may be n-type doped regions. The features of other elements or layers of the electronic unit EU may refer to the contents above, and will not be redundantly described. It should be noted that the structure of the electronic unit EU shown in FIG. 15 is exemplary, and the present disclosure is not limited thereto.

As mentioned above, the electronic unit EU of the present embodiment may include three electrodes, that is, the gate electrode GE, the source electrode SE and the drain electrode DE mentioned above. In other words, the electronic unit EU may have three signal connecting points (that is, the above-mentioned N1 is 3). The structure shown in FIG. 15 may be the cross-sectional structure of the structure shown in FIG. 14 along a section line A-A′. Specifically, as shown in FIG. 14, the electronic unit EU may include the first electrode EL1, the second electrode EL2 and the third electrode EL3, wherein the third electrode EL3 may be the source electrode SE, the second electrode EL2 may be the gate electrode GE, and the first electrode EL1 may be the drain electrode DE, but not limited thereto. In the present embodiment, the first electrode EL1 may have any suitable solid pattern and substantially be disposed at the center of the electronic unit EU, the second electrode EL2 may have any suitable ring structure and surround the first electrode EL1, and the third electrode EL3 may have any suitable ring structure and surround the first electrode EL1 and the second electrode EL2. The above-mentioned equation (1) to equation (5) may be applied to the present embodiment, wherein N1 may be 3. Specifically, the range of the width W1 of the electrodes of the electronic unit EU shown in the equation (2) to the equation (4) mentioned above may be applied to the widths of the first electrode EL1, the second electrode EL2 and the third electrode EL3 of the present embodiment. In addition, the minimum distance W2 in the above-mentioned equation (5) may be the distance between the interconnection element (or the via) corresponding to the first electrode EL1 and the interconnection element (or the via) corresponding to the second electrode EL2 or the distance between the interconnection element (or the via) corresponding to the second electrode EL2 and the interconnection element (or the via) corresponding to the third electrode EL3.

In summary, an electronic device including a substrate and electronic units is provided by the present disclosure. The substrate includes recesses, and the electronic units may be disposed in the recesses through a massive transfer process, such as a fluid transfer process. The electronic device may further include a conductive layer disposed on the substrate, and the conductive layer may include interconnection elements electrically connected to the electronic units. According to the present disclosure, through the size designs of the electronic unit and the recess, the pattern design and the width design of the electrodes of the electronic unit, and the distance design of the interconnection elements, the influence of the randomness of the distribution of the electronic units in the recesses on the electrical connection between the electronic units and the conductive layer may be reduced under the condition of the fixed configuration of the conductive layer. Therefore, the success rate of the massive transfer process may increase, or the yield of the electronic device may increase.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate comprising at least one recess; and
at least one electronic unit disposed in the at least one recess, wherein the at least one electronic unit has N1 signal connecting points, and N1 is greater than or equal to 1,
wherein in a top view direction of the electronic device, the at least one recess has a maximum size D1, the at least one electronic unit has a maximum size C1, and the maximum size D1 and the maximum size C1 satisfy:
$$0 < D 1 - C 1 < C 1 / N 1 .$$

2. The electronic device according to claim 1, wherein the substrate comprises:
a base;
a circuit layer disposed on the base; and
an insulating layer disposed on the circuit layer,
wherein the at least one recess is disposed in the insulating layer.

3. The electronic device according to claim 2, further comprising:
an encapsulation layer disposed on the insulating layer and covering the at least one electronic unit; and
a conductive layer disposed on the encapsulation layer,
wherein the encapsulation layer comprises at least one via, and
the conductive layer is electrically connected to the at least one electronic unit through the at least one via.

4. The electronic device according to claim 1, wherein in the top view direction of the electronic device, the at least one recess is circular and has a radius R1, the at least one electronic unit is square and has at least one electrode, the at least one electrode has a width W1, wherein the width W1 satisfies:
$$0 < W 1 < \frac{\sqrt{2} R 1}{2 N 1 - 1} .$$

5. The electronic device according to claim 4, wherein the width W1 satisfies:
$$0 < W 1 < \frac{\sqrt{2} R 1}{4 N 1 - 2} .$$

6. The electronic device according to claim 4, further comprising a conductive layer disposed on the substrate, the conductive layer is electrically connected to the at least one electronic unit through a first via and a second via adjacent to the first via, a minimum distance W2 is included between the first via and the second via, wherein the minimum distance W2 satisfies:
$$0 < W 1 < \frac{2 \sqrt{2} R 1}{2 N 1 - 1} .$$

7. The electronic device according to claim 1, wherein the at least one electronic unit comprises a light emitting diode.

8. The electronic device according to claim 7, wherein N1 is 2.

9. The electronic device according to claim 7, wherein the at least one electronic unit comprises:
a first semiconductor layer;
a second semiconductor layer;
an active layer disposed between the first semiconductor layer and the second semiconductor layer;
a first electrode disposed at a side of the first semiconductor layer opposite to the active layer and electrically connected to the first semiconductor layer; and
a second electrode disposed at the side of the first semiconductor layer opposite to the active layer and electrically connected to the second semiconductor layer,
wherein in the top view direction of the electronic device, the second electrode surrounds the first electrode.

10. The electronic device according to claim 9, wherein the at least one electronic unit has a top surface, the top surface has an edge, and in the top view direction of the electronic device, the second electrode is protruded from the edge.

11. The electronic device according to claim 9, wherein the at least one electronic unit has a top surface, the top surface has an edge, and in the top view direction of the electronic device, an outline of the second electrode is overlapped with the edge.

12. The electronic device according to claim 9, wherein the first electrode and the second electrode are further disposed at a side of the second semiconductor layer opposite to the active layer.

13. The electronic device according to claim 9, wherein in the top view direction of the electronic device, the second electrode has a round-corner structure or a chamfering structure.

14. The electronic device according to claim 9, wherein the at least one electronic unit further comprises a passivation layer disposed between the first electrode and the second electrode, and the passivation layer electrically insulates the first electrode and the second electrode.

15. The electronic device according to claim 9, further comprising a conductive layer disposed on the substrate, wherein the conductive layer is electrically connected to the first electrode through a first via and electrically connected to the second electrode through a second via, and in the top view direction of the electronic device, an area of the second via is greater than an area of the first via.

16. The electronic device according to claim 9, wherein the second electrode has a symmetrical pattern.

17. The electronic device according to claim 1, wherein the at least one electronic unit comprises a metal-oxide-semiconductor field-effect transistor.

18. The electronic device according to claim 17, wherein the at least one electronic unit comprises a first electrode, a second electrode and a third electrode, the second electrode surrounds the first electrode, and the third electrode surrounds the first electrode and the second electrode.

19. The electronic device according to claim 17, wherein N1 is 3.

20. The electronic device according to claim 1, wherein the recess penetrates through the insulating layer.
